(19) United States
(12) Patent Application Publication
(10) Pub. No.: US 2019/0348533 A1
(43) Pub. Date: Nov. 14, 2019

(54) LATERAL DOUBLE DIFFUSED METAL OXIDE SEMICONDUCTOR DEVICE AND MANUFACTURING METHOD THEREOF

(71) Applicant: RICHTEK TECHNOLOGY CORPORATION, Zhubei City (TW)

(72) Inventor: Tsung-Yi Huang, Hsinchu (TW)

(21) Appl. No.: 16/297,660

(22) Filed: Mar. 10, 2019

(30) Foreign Application Priority Data
May 8, 2018 (TW) 107115630

(51) Int. Cl. H01L 29/78; H01L 29/06; H01L 29/10; H01L 29/66; H01L 21/762; H01L 21/02

(52) U.S. Cl. CPC H01L 29/7816; H01L 29/0649; H01L 21/0228; H01L 29/66681; H01L 21/76202; H01L 29/1095

(57) ABSTRACT

A lateral double diffused metal oxide semiconductor (LDMOS) device includes: a semiconductor layer, an isolation oxide region, a first drift oxide region, a second drift oxide region, a well region, a body region, a gate, a source, and a drain. The isolation oxide region, the first drift oxide region, and the second drift oxide region have an isolation thickness, a first thickness, and a second thickness respectively in a vertical direction, wherein the second thickness is less than the first thickness. The second drift oxide region is a chemical vapor deposition (CVD) oxide region, and is formed by a CVD process step. The first drift oxide region is a local oxidation of silicon (LOCOS) structure or a shallow trench isolation (STI) structure.

### CROSS REFERENCES

The present invention claims priority to TW 107115630 filed on May 8, 2018.

### BACKGROUND OF THE INVENTION

### Field of Invention

The present invention relates to a lateral double diffused metal oxide semiconductor (LDMOS) device and a manufacturing method thereof; particularly, the present invention relates to an LDMOS device having a lowered on-resistance while maintaining the breakdown protection voltage, and a manufacturing method thereof.

### Description of Related Art

FIGS. 1A and 1B are a cross-sectional view and a top view, respectively, of a conventional lateral double diffused metal oxide semiconductor (LDMOS) device 100. As shown in FIGS. 1A and 1B, the LDMOS device 100 includes a well region 12, an isolation oxide region 13, a first drift oxide region 14, a body region 16, a gate 17, a source 18, and a drain 19. The conductivity type of the well region 12 is N-type, which is formed on the substrate 11; the isolation oxide region 13 is a local oxidation of silicon (LOCOS) structure, which defines an operation region 13a of the LDMOS device 100. The range of the operation region 13a is indicated by the thick black dashed line in FIG. 1B. The gate 17 covers a portion of the first drift oxide region 14. To increase the withstand voltage of the LDMOS device 100, one possible way is to increase the thickness of the isolation oxide region 13 and the first drift oxide region 14, but this will also increase the on-resistance of the high voltage device 100, and as a result, the operation speed is lowered, degrading the performance of the device.

In view of this, the present invention provides a LDMOS device having a lowered on-resistance while maintaining the breakdown protection voltage, and a manufacturing method thereof.

### SUMMARY OF THE INVENTION

From one perspective, the present invention provides a lateral double diffused metal oxide semiconductor (LDMOS) device comprising: a semiconductor layer formed on a substrate, wherein the semiconductor layer has a top surface and a bottom surface that is opposite to the top surface in a vertical direction; an isolation oxide region formed on the top surface and in contact with the top surface, wherein the isolation oxide region defines an operation region; a first drift oxide region formed on the top surface and in contact with the top surface, wherein the first drift oxide region is located on a drift region in the operation region and in contact with the drift region; a second drift oxide region formed on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction; a well region having a first conductivity type, wherein the well region is formed in the operation region of the semiconductor layer and is located beneath the top surface and in contact with the top surface in the vertical direction; a body region having a second conductivity type, wherein the body region is formed in the well region of the operation region and is located beneath the top surface and in contact with the top surface; a gate formed on the top surface in the operation region of the semiconductor layer, wherein the gate covers all the second drift oxide region and at least a portion of the first drift oxide region, and wherein the gate comprises: a dielectric layer formed on the the top surface and in contact with the top surface, wherein the dielectric layer is in contact with the second drift oxide region in the lateral direction, and the dielectric layer and the first drift oxide region and are separated by the second drift oxide region; a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and a spacer layer formed outside sidewalls of the conductive layer, wherein the spacer layer is in contact with the conductive layer and serves as an electrical insulation layer of the gate; a source having the first conductivity type, wherein the source is formed beneath the top surface and in contact with the top surface in the vertical direction in the body region of the semiconductor layer; and a drain having the first conductivity type, wherein the drain is formed beneath the top surface and in contact with the top surface in the vertical direction in the well region of the semiconductor layer, and the drain is located between the first drift oxide region and the isolation oxide region; wherein the source is located in the body region outside the gate and the drain is located at a location in the well region which is away from the body region; wherein the drift region is defined as a region between the drain and the body region in the well region and near the top surface, for ON operation of the high voltage device; wherein the isolation oxide region, the first drift oxide region, and the second drift oxide region have an isolation thickness, a first thickness, and a second thickness respectively in the vertical direction, wherein the second thickness is less than the first thickness; wherein the second drift oxide region is a chemical vapor deposition (CVD) oxide region which is formed by a CVD process step; wherein the first drift oxide region is a local oxidation of silicon (LOCOS) structure or a shallow trench isolation (STI) structure; and wherein the second thickness is larger than a dielectric layer thickness of the dielectric layer.

From another perspective, the present invention provides a manufacturing method of a lateral double diffused metal oxide semiconductor (LDMOS), comprising: forming a semiconductor layer on a substrate, wherein the semiconductor layer has a top surface and a bottom surface that is opposite to the top surface in a vertical direction; forming an isolation oxide region on the top surface and in contact with the top surface, wherein the isolation oxide region defines an operation region; forming a first drift oxide region on the top surface and in contact with the top surface, wherein the first drift oxide region is located on a drift region in the operation region and in contact with the drift region; forming a second drift oxide region on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction; forming a well region having a first conductivity type, wherein the well region is formed in the operation region of the semiconductor layer and is located beneath the top surface and in contact with the top surface in the vertical direction; forming a body region having a second conductivity type, wherein the body region is formed in the well region of the operation region and is located beneath the top surface and in contact with the top surface; forming a gate on the top surface in the operation region of the semiconductor layer, wherein the gate covers all the second drift oxide region and at least a portion of the first drift oxide region, and wherein the gate comprises: a dielectric layer formed on the the top surface and in contact with the top surface, wherein the dielectric layer is in contact with the second drift oxide region in the lateral direction, and the dielectric layer and the first drift oxide region and are separated by the second drift oxide region; a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and a spacer layer formed outside sidewalls of the conductive layer, wherein the spacer layer is in contact with the conductive layer and serves as an electrical insulation layer of the gate; forming a source having the first conductivity type, wherein the source is formed beneath the top surface and in contact with the top surface in the vertical direction in the body region of the semiconductor layer; and forming a drain having the first conductivity type, wherein the drain is formed beneath the top surface and in contact with the top surface in the vertical direction in the well region of the semiconductor layer, and the drain is located between the first drift oxide region and the isolation oxide region; wherein the source is located in the body region outside the gate and the drain is located at a location in the well region which is away from the body region; wherein the drift region is defined as a region between the drain and the body region in the well region and near the top surface, for ON operation of the high voltage device; wherein the isolation oxide region, the first drift oxide region, and the second drift oxide region have an isolation thickness, a first thickness, and a second thickness respectively in the vertical direction, wherein the second thickness is less than the first thickness; wherein the second drift oxide region is a chemical vapor deposition (CVD) oxide region which is formed by a CVD process step; wherein the first drift oxide region is a local oxidation of silicon (LOCOS) structure or a shallow trench isolation (STI) structure; and wherein the second thickness is larger than a dielectric layer thickness of the dielectric layer.

From another perspective, the present invention provides a lateral double diffused metal oxide semiconductor (LDMOS) device comprising: a semiconductor layer formed on a substrate, wherein the semiconductor layer has a top surface and a bottom surface that is opposite to the top surface in a vertical direction; an isolation oxide region formed on the top surface and in contact with the top surface, wherein the isolation oxide region defines an operation region; a first drift oxide region formed on the top surface and in contact with the top surface, wherein the first drift oxide region is located on a drift region in the operation region and in contact with the drift region; a second drift oxide region formed on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction; a drift well region having a first conductivity type, wherein the drift well region is formed in the operation region of the semiconductor layer and is located beneath the top surface and in contact with the top surface in the vertical direction; a channel well region having a second conductivity type, wherein the channel well region is formed at least in the operation region beneath the top surface in the vertical direction and in contact with the drift well region in the lateral direction; a buried layer having the first conductivity type, wherein the buried layer is formed beneath the channel well region and in contact with the channel well region in the vertical direction, and wherein the buried layer completely covers a portion of the the channel well region in the operation region; a gate formed on the top surface in the operation region of the semiconductor layer, wherein the gate covers all the second drift oxide region and at least a portion of the first drift oxide region, and wherein the gate comprises: a dielectric layer formed on the the top surface and in contact with the top surface, wherein the dielectric layer is in contact with the second drift oxide region in the lateral direction, and the dielectric layer and the first drift oxide region and are separated by the second drift oxide region; a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and a spacer layer formed outside sidewalls of the conductive layer, wherein the spacer layer is in contact with the conductive layer and serves as an electrical insulation layer of the gate; a source having the first conductivity type, wherein the source is formed beneath the top surface and in contact with the top surface in the vertical direction in the channel well region of the semiconductor layer; and a drain having the first conductivity type, wherein the drain is formed beneath the top surface and in contact with the top surface in the drift well region of the semiconductor layer in the vertical direction and the drain is located between the first drift region and the isolation oxide region; wherein the source is located in the channel well region outside the gate and the drain is located at a location in the drift well region which is away from the channel well region; wherein the drift region is defined as a region between the drain and the channel well region in the drift well region and near the top surface, for ON operation of the high voltage device; wherein the isolation oxide region, the first drift oxide region, and the second drift oxide region have an isolation thickness, a first thickness, and a second thickness respectively in the vertical direction, wherein the second thickness is less than the first thickness; wherein the second drift oxide region is a chemical vapor deposition (CVD) oxide region which is formed by a CVD process step; wherein the first drift oxide region is a local oxidation of silicon (LOCOS) structure or a shallow trench isolation (STI) structure; and wherein the second thickness is larger than a dielectric layer thickness of the dielectric layer.

From another perspective, the present invention provides a manufacturing method of a lateral double diffused metal oxide semiconductor (LDMOS) device, comprising: forming a semiconductor layer on a substrate, wherein the semiconductor layer has a top surface and a bottom surface that is opposite to the top surface in a vertical direction; forming an isolation oxide region on the top surface and in contact with the top surface, wherein the isolation oxide region defines an operation region; forming a first drift oxide region on the top surface and in contact with the top surface, wherein the first drift oxide region is located on a drift region in the operation region and in contact with the drift region; forming a second drift oxide region on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction; forming a drift well region having a first conductivity type, wherein the drift well region is formed in the operation region of the semiconductor layer and is located beneath the top surface and in contact with the top surface in the vertical direction; forming a channel well region having a second conductivity type, wherein the channel well region is formed at least in the operation region beneath the top surface in the vertical direction and in contact with the drift well region in the lateral direction; forming a buried layer having the first conductivity type, wherein the buried layer is formed beneath the channel well region and in contact with the channel well region in the vertical direction, and wherein the buried layer completely covers a portion of the the channel well region in the operation region; forming a gate on the top surface in the operation region of the semiconductor layer, wherein the gate covers all the second drift oxide region and at least a portion of the first drift oxide region, and wherein the gate comprises: a dielectric layer formed on the the top surface and in contact with the top surface, wherein the dielectric layer is in contact with the second drift oxide region in the lateral direction, and the dielectric layer and the first drift oxide region and are separated by the second drift oxide region; a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and a spacer layer formed outside sidewalls of the conductive layer, wherein the spacer layer is in contact with the conductive layer and serves as an electrical insulation layer of the gate; forming a source having the first conductivity type, wherein the source is formed beneath the top surface and in contact with the top surface in the vertical direction in the channel well region of the semiconductor layer; and forming a drain having the first conductivity type, wherein the drain is formed beneath the top surface and in contact with the top surface in the vertical direction in the drift well region of the semiconductor layer, and the drain is located between the first drift region and the isolation oxide region; wherein the source is located in the channel well region outside the gate and the drain is located at a location in the drift well region which is away from the channel well region; wherein the drift region is defined as a region between the drain and the channel well region in the drift well region and near the top surface, for ON operation of the high voltage device; wherein the isolation oxide region, the first drift oxide region, and the second drift oxide region have an isolation thickness, a first thickness, and a second thickness respectively in the vertical direction, wherein the second thickness is less than the first thickness; wherein the second drift oxide region is a chemical vapor deposition (CVD) oxide region which is formed by a CVD process step; wherein the first drift oxide region is a local oxidation of silicon (LOCOS) structure or a shallow trench isolation (STI) structure; and wherein the second thickness is larger than a dielectric layer thickness of the dielectric layer.

In one preferable embodiment, the isolation oxide region, the drain, the first drift oxide region, the second drift oxide region and the dielectric layer are arranged in a sequential order in the lateral direction.

In one preferable embodiment, the LDMOS device further includes a body electrode having the second conductivity type, wherein the body electrode is formed in the body region and serves as an electrical contact of the body region.

The objectives, technical details, features, and effects of the present invention will be better understood with regard to the detailed description of the embodiments below.

### BRIEF DESCRIPTION OF THE DRAWINGS

FIGS. 1A and 1B show a conventional LDMOS device 100.

FIGS. 2A and 2B show a first embodiment of the present invention.

FIGS. 3A and 3B show a second embodiment of the present invention.

FIGS. 4A and 4B show a third embodiment of the present invention.

FIGS. 5A and 5B show a fourth embodiment of the present invention.

FIGS. 6A to 6J show a fifth embodiment of the present invention.

FIGS. 7A to 7I show a sixth embodiment of the present invention.

### DESCRIPTION OF THE PREFERABLE EMBODIMENTS

The drawings as referred to throughout the description of the present invention are for illustration only, to show the interrelations among the process steps and the layers; the shapes, thicknesses, and widths are not drawn in actual scale.

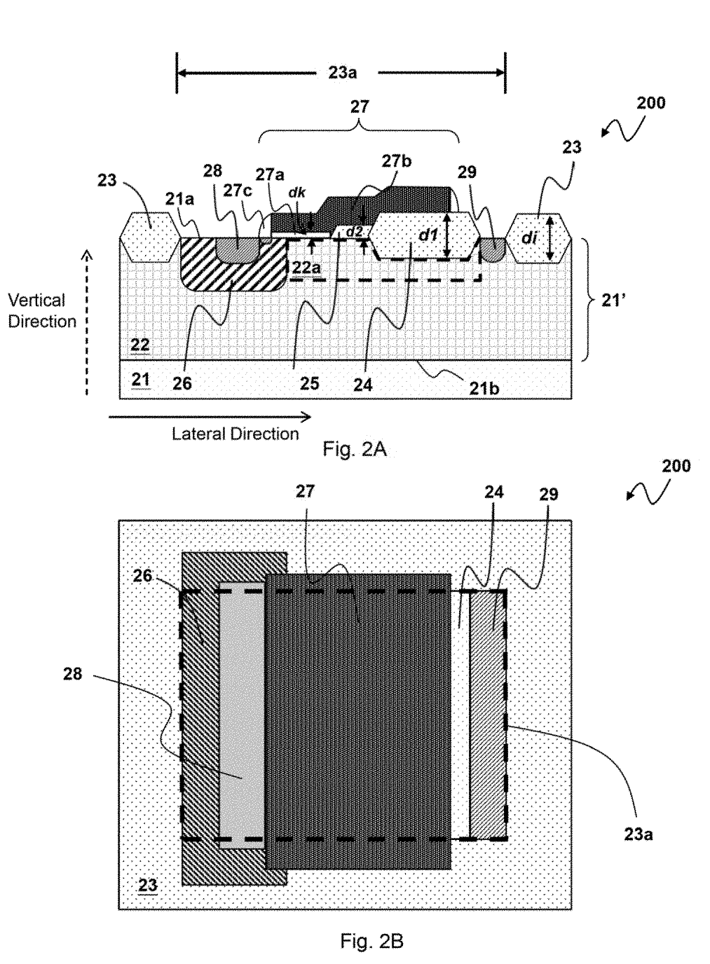

FIGS. 2A and 2B show a first embodiment of the present invention. FIGS. 2A and 2B respectively show a cross-sectional view and a top view of a high voltage device 200. The high voltage device 200 includes a semiconductor layer 21′, a well region 22, an isolation oxide region 23, a first drift oxide region 24, a second drift oxide region 25, a body region 26, a gate 27, a source 28, and a drain 29. The semiconductor layer 21′ is formed on the substrate 21, and the semiconductor layer 21′ has a top surface 21a and a bottom surface 21b that is opposite to the top surface 21a in a vertical direction (as indicated by the direction of the dashed arrow in FIG. 2A). The substrate 21 is, for example but not limited to, a P-type or N-type semiconductor silicon substrate. The semiconductor layer 21′, for example, is formed on the substrate 21 by epitaxy, or, a part of the substrate 21 forms the semiconductor layer 21′. The method of forming the semiconductor layer 21′ is known to a person having ordinary skill in the art, so the details thereof are not redundantly explained here.

Still referring to FIGS. 2A and 2B, the isolation oxide region 23 is formed on the top surface 21a and in contact with the top surface 21a for defining an operation region 23a (as indicated by the dashed line in FIG. 2B). The isolation oxide region 23 is not limited to the local oxidation of silicon (LOCOS) structure as shown in the figure, and may instead be a shallow trench isolation (STI) structure. The first drift oxide region 24 is formed on the top surface 21a and in contact with the top surface 21a, and is located on the drift region 22a (as indicated by the dashed line in FIG. 2A) in the operation region 23a and in contact with the drift region 22a. The second drift oxide region 25 is formed on the top surface 21a and in contact with the top surface 21a, and is located on the drift region 22a in the operation region 23a and in contact with the drift region 22a, and the second drift oxide region 25 is in contact with the first drift oxide region 24 in a lateral direction (as indicated by the direction of the solid arrow in FIG. 2A).

The well region 22 which has a first conductivity type is formed in the operation region 23a of the semiconductor layer 21′, and the well region 22 is located beneath the top surface 21a and in contact with the top surface 21a in the vertical direction. The body region 26 which has a second conductivity type is formed in the well region 22 of the semiconductor layer 21′, and the body region 26 is located beneath the top surface 21a and in contact with the top surface 21a in the vertical direction. The gate 27 is formed on the top surface 21a in the operation region 23a of the semiconductor layer 21′. As viewing from above (i.e., from top view), the gate 27 covers all the second drift oxide region 25 and at least a portion of the first drift oxide region 24; a portion of the body region 26 is located beneath the gate 27 and in contact with the gate 27 in the vertical direction, to provide an inverse current channel during ON operation of the high voltage device 200.

Still referring to FIGS. 2A and 2B, the gate 27 includes a dielectric layer 27a, a conductive layer 27b, and a spacer layer 27c. The dielectric layer 27a is formed on the top surface 21a and in contact with the top surface 21a, and in contact with the second drift oxide region 25 in the lateral direction, and the dielectric layer 27a and the first drift oxide region 24 are separated by the second drift oxide region 25. The conductive layer 27b which is provided as an electrical contact of the gate 27 is formed on all the dielectric layers 27a and in contact with the dielectric layer 27a, and is formed on all the second drift oxide regions 25 and in contact with the second drift oxide region 25, and is formed on at least a portion of the first drift oxide region 24 and in contact with the first drift oxide region 24. The spacer layer 27c is formed outside the sidewalls of the conductive layer 27b and in contact with the conductive layer 27b so as to serve as an electrical insulation layer of the gate 27. (The spacer layer 27c is deposited as one layer but etched later to become separate parts; in the context of the present invention, a singular form “spacer layer” is used because the separate parts belong to one layer.)

The source 28 which has the first conductivity type is formed beneath the top surface 21a in the body region 26 of the semiconductor layer 21′, and in contact with the top surface 21a in the vertical direction. The drain 29 which has the first conductivity type is formed beneath the top surface 21a in the well region 22 of the semiconductor layer 21′, and in contact with the top surface 21a in the vertical direction. From top view, the drain 29 is between the first drift oxide region 24 and the isolation oxide region 23. The source 28 is located in the body region 26 outside the gate 27 and the drain 29 is located in the well region 22 at a location away from the body region 26 in the lateral direction. The drift region 22a is defined between the drain 29 and the body region 26 in the well region 22 and near the top surface 21a, to serve as the drift region during ON operation of the high voltage device 200.

The isolation oxide region 23, the first drift oxide region 24, and the second drift oxide region 25 have an insulation thickness di, a first thickness d1, and a second thickness d2 in the vertical direction, respectively, and the second thickness d2 is less than the first thickness D1. The second drift oxide region 25 is a chemical vapor deposition (CVD) oxide region formed by a CVD process step. The CVD process step is well known to a person having ordinary skill in the art, so the details thereof are not redundantly explained here. The first drift oxide region 24 is a local oxidation of silicon (LOCOS) structure as shown in the figure. The second thickness d2 is larger than a dielectric layer thickness dk of the dielectric layer 27a.

Note that the term “inverse current channel” means thus. Taking this embodiment as an example, when the high voltage device 200 operates in ON operation due to the voltage applied to the gate 27, an inversion layer is formed beneath the gate 27 so that a conduction current flows through the region of the inversion layer, which is the inverse current channel known to a person having ordinary skill in the art.

Note that the term “drift region” means thus. Taking this embodiment as an example, the drift region refers to a region where the conduction current passes through in a drifting manner when the high-voltage device 200 operates in ON operation, which is known to a person having ordinary skill in the art.

Note that the top surface 21a as referred to in this embodiment does not mean a completely flat plane but refers to the surface of the semiconductor layer 21′. In the present embodiment, for example, a part of the top surface 21a where the drift oxide region 24 is in contact with has a recessed portion.

Note that the above-mentioned “first conductivity type” and “second conductivity type” mean that impurities of corresponding conductivity types are doped in regions of the high voltage MOS device (for example but not limited to the aforementioned well region, body region, source and drain, etc.), so that the regions have the corresponding conductivity types. For example the first conductivity type is N-type and the second conductivity type is P-type, or the first conductivity type is P-type and the second conductivity type is N-type.

In addition, the term “high voltage” MOS device means that, when the device operates in normal operation, the voltage applied to the drain is higher than a specific voltage, such as 5V; for devices of different high voltages, a lateral distance (drift distance) between the body region 26 and the drain 29 can be set according to the operation voltage that the device is required to withstand during normal operation, which is known to a person having ordinary skill in the art.

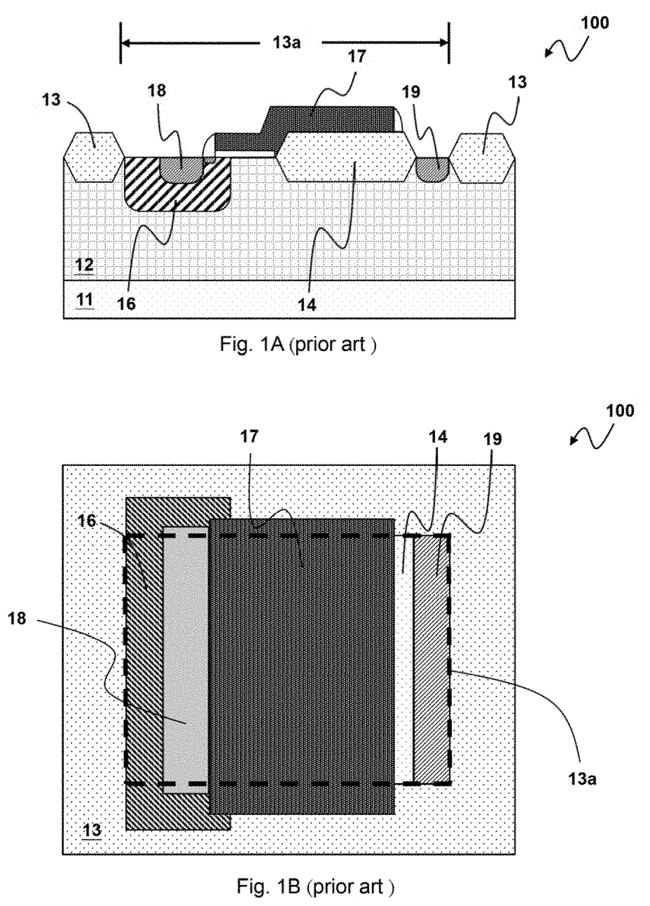

The present invention is superior to the prior art in that: according to the present invention, a portion of the drift oxide region beneath the gate near the source side in the prior art is replaced by a CVD oxide region having a less thickness (comparing the first drift oxide region 14 in FIG. 1A with the second drift oxide region 25 in FIG. 2A), so that the on-resistance can be lowered, the on-current can be increased, and the speed and application range of the device can be increased without lowering the breakdown protection voltage. In addition, the junction between the CVD oxide region and the drift region is at the same elevation level in the vertical direction as the topmost level of the inverse current channel, but in the prior art, the junction between the drift oxidate region and the drift region is lower than the topmost level of the inverse current channel, so in the prior art, the on-current path is longer, while in the present invention, the on-current path is shorter whereby the on-resistance is reduced.

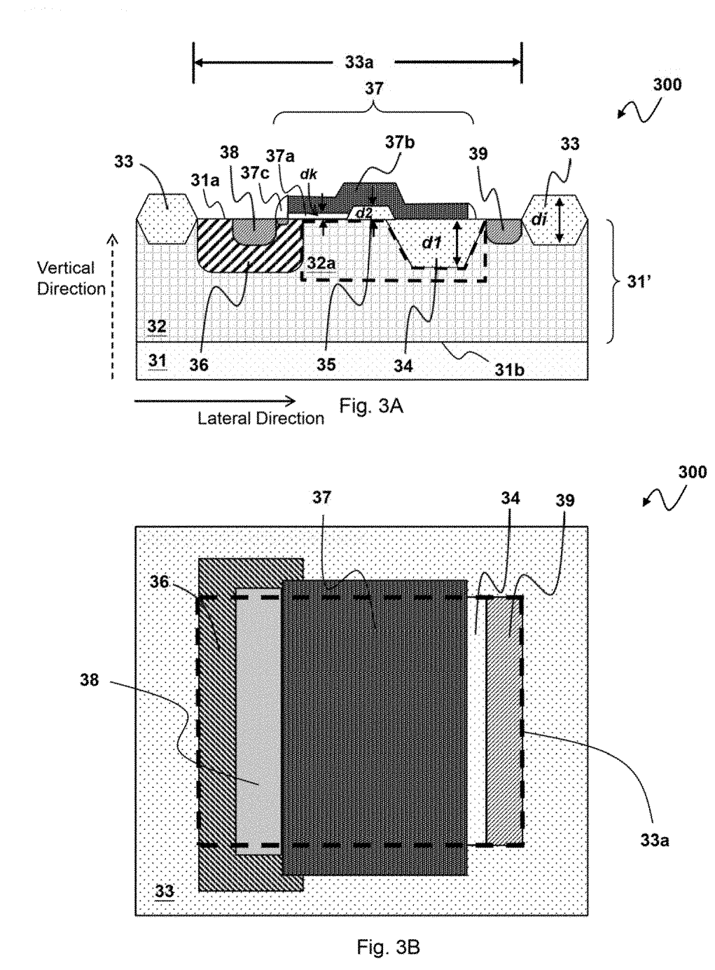

Please refer to FIGS. 3A and 3B, which show a second embodiment of the present invention. FIGS. 3A and 3B respectively show a cross-sectional view and a top view of a high voltage device 300. The high voltage device 300 includes a semiconductor layer 31′, a well region 32, an isolation oxide region 33, a first drift oxide region 34, a second drift oxide region 35, a body region 36, a gate 37, a source 38, and a drain 39. The semiconductor layer 31′ is formed on the substrate 31, and the semiconductor layer 31′ has a top surface 31a and a bottom surface 31b that is opposite to the top surface 31a in a vertical direction (as indicated by the direction of the dashed arrow in FIG. 3A). The substrate 31 is, for example but not limited to, a P-type or N-type semiconductor silicon substrate. The semiconductor layer 31′, for example, is formed on the substrate 31 by epitaxy, or, a part of the substrate 31 forms the semiconductor layer 31′. The method of forming the semiconductor layer 31′ is known to a person having ordinary skill in the art, so the details thereof are not redundantly explained here.

Still referring to FIGS. 3A and 3B, the isolation oxide region 33 is formed on the top surface 31a and in contact with the top surface 31a for defining an operation region 33a (as indicated by the dashed line in FIG. 3B). The isolation oxide region 33 is not limited to the local oxidation of silicon (LOCOS) structure as shown in the figure, and may instead be a shallow trench isolation (STI) structure. The first drift oxide region 34 is formed on the top surface 31a and in contact with the top surface 31a, and is located on the drift region 32a (as indicated by the dashed line in FIG. 3A) in the operation region 33a and in contact with the drift region 32a. The second drift oxide region 35 is formed on the top surface 31a and in contact with the top surface 31a, and is located on the drift region 32a in the operation region 33a and in contact with the drift region 32a, and the second drift oxide region 35 is in contact with the first drift oxide region 34 in a lateral direction (as indicated by the direction of the solid arrow in FIG. 3A).

The well region 32 which has a first conductivity type is formed in the operation region 33a of the semiconductor layer 31′, and the well region 32 is located beneath the top surface 31a and in contact with the top surface 31a in the vertical direction. The body region 36 which has a second conductivity type is formed in the well region 32 of the semiconductor layer 31′, and the body region 36 is located beneath the top surface 31a and in contact with the top surface 31a in the vertical direction. The gate 37 is formed on the top surface 31a in the operation region 33a of the semiconductor layer 31′. As viewing from above (i.e., from top view), the gate 37 covers all the second drift oxide region 35 and at least a portion of the first drift oxide region 34; a portion of the body region 36 is located beneath the gate 37 and in contact with the gate 37 in the vertical direction, to provide an inverse current channel during ON operation of the high voltage device 300.

Still referring to FIGS. 3A and 3B, the gate 37 includes a dielectric layer 37a, a conductive layer 37b, and a spacer layer 37c. The dielectric layer 37a is formed on the top surface 31a and in contact with the top surface 31a, and in contact with the second drift oxide region 35 in the lateral direction, and the dielectric layer 37a and the first drift oxide region 34 are separated by the second drift oxide region 35. The conductive layer 37b which is provided as an electrical contact of the gate 37 is formed on all the dielectric layers 37a and in contact with the dielectric layer 37a, and is formed on all the second drift oxide regions 35 and in contact with the second drift oxide region 35, and is formed on at least a portion of the first drift oxide region 34 and in contact with the first drift oxide region 34. The spacer layer 37c is formed outside the sidewalls of the conductive layer 37b and in contact with the conductive layer 37b so as to serve as an electrical insulation layer of the gate 37.

The source 38 which has the first conductivity type is formed beneath the top surface 31a in the body region 36 of the semiconductor layer 31′, and in contact with the top surface 31a in the vertical direction. The drain 39 which has the first conductivity type is formed beneath the top surface 31a in the well region 32 of the semiconductor layer 31′, and in contact with the top surface 31a in the vertical direction. From top view, the drain 39 is between the first drift oxide region 34 and the isolation oxide region 33. The source 38 is located in the body region 36 outside the gate 37 and the drain 39 is located in the well region 32 at a location away from the body region 36 in the lateral direction. The drift region 32a is defined between the drain 39 and the body region 36 in the well region 32 and near the top surface 31a, to serve as the drift region during ON operation of the high voltage device 300.

The isolation oxide region 33, the first drift oxide region 34, and the second drift oxide region 35 have an insulation thickness di, a first thickness d1, and a second thickness d2 in the vertical direction, respectively, and the second thickness d2 is less than the first thickness D1. The second drift oxide region 35 is a chemical vapor deposition (CVD) oxide region formed by a CVD process step; the CVD process step is well known to a person having ordinary skill in the art, so the details thereof are not redundantly explained here. The first drift oxide region 34 is a shallow trench isolation (STI) region as shown in the figure. The second thickness d2 is larger than a dielectric layer thickness dk of the dielectric layer 37a.

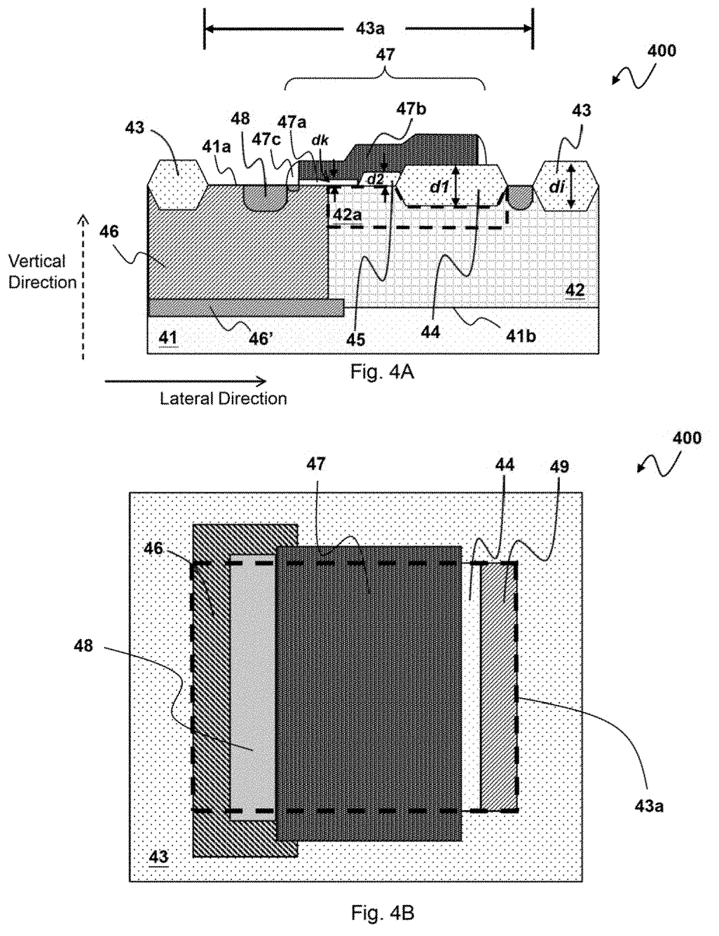

FIGS. 4A and 4B show a third embodiment of the present invention. FIGS. 4A and 4B respectively show a cross-sectional view and a top view of a high voltage device 400. The high voltage device 400 includes a semiconductor layer 41′, a drift well region 42, a buried layer 46′, an isolation oxide region 43, a first drift oxide region 44, a second drift oxide region 45, a channel well region 46, a gate 47, a source 48, and a drain 49. The semiconductor layer 41′ is formed on the substrate 41, and the semiconductor layer 41′ has a top surface 41a and a bottom surface 41b that is opposite to the top surface 41a in a vertical direction (as indicated by the direction of the dashed arrow in FIG. 4A). The substrate 41 is, for example but not limited to, a P-type or N-type semiconductor silicon substrate. The semiconductor layer 41′, for example, is formed on the substrate 41 by epitaxy, or, a part of the substrate 41 forms the semiconductor layer 41′. The method of forming the semiconductor layer 41′ is known to a person having ordinary skill in the art, so the details thereof are not redundantly explained here.

Still referring to FIGS. 4A and 4B, the isolation oxide region 43 is formed on the top surface 41a and in contact with the top surface 41a for defining an operation region 43a (as indicated by the dashed line in FIG. 4B). The isolation oxide region 43 is not limited to the local oxidation of silicon (LOCOS) structure as shown in the figure, and may instead be a shallow trench isolation (STI) structure. The first drift oxide region 44 is formed on the top surface 41a and in contact with the top surface 41a, and is located on the drift region 42a (as indicated by the dashed line in FIG. 4A) in the operation region 43a and in contact with the drift region 42a. The second drift oxide region 45 is formed on the top surface 41a and in contact with the top surface 41a, and is located on the drift region 42a in the operation region 43a and in contact with the drift region 42a, and the second drift oxide region 45 is in contact with the first drift oxide region 44 in a lateral direction (as indicated by the direction of the solid arrow in FIG. 4A).

The drift well region 42 which has a first conductivity type is formed in the operation region 43a of the semiconductor layer 41′, and the drift well region 42 is located beneath the top surface 41a and in contact with the top surface 41a in the vertical direction. The channel well region 46 (or a portion thereof) which has a second conductivity type is formed in the operation region 43a of the semiconductor layer 41′, and the channel well region 46 is located beneath the top surface 41a and in contact with the top surface 41a in the vertical direction. The buried layer 46′ which has the first conductivity type is formed beneath the channel well region 46 and in contact with the channel well region 46, and the buried layer 46′ covers the whole lower side of at least the portion of the channel well region 46 in the operation region 43a. The gate 47 is formed on the top surface 41a in the operation region 43a of the semiconductor layer 41′. As viewing from above (i.e., from top view), the gate 47 covers all the second drift oxide region 45 and at least a portion of the first drift oxide region 44; a portion of the channel well region 46 is located beneath the gate 47 and in contact with the gate 47 in the vertical direction, to provide an inverse current channel during ON operation of the high voltage device 400.

Still referring to FIGS. 4A and 4B, the gate 47 includes a dielectric layer 47a, a conductive layer 47b, and a spacer layer 47c. The dielectric layer 47a is formed on the top surface 41a and in contact with the top surface 41a, and in contact with the second drift oxide region 45 in the lateral direction, and the dielectric layer 47a and the first drift oxide region 44 are separated by the second drift oxide region 45. The conductive layer 47b which is provided as an electrical contact of the gate 47 is formed on all the dielectric layers 47a and in contact with the dielectric layer 47a, and is formed on all the second drift oxide regions 45 and in contact with the second drift oxide region 45, and is formed on at least a portion of the first drift oxide region 44 and in contact with the first drift oxide region 44. The spacer layer 47c is formed outside the sidewalls of the conductive layer 47b and in contact with the conductive layer 47b so as to serve as an electrical insulation layer of the gate 47.

The source 48 which has the first conductivity type is formed beneath the top surface 41a in the channel well region 46 of the semiconductor layer 41′, and in contact with the top surface 41a in the vertical direction. The drain 49 which has the first conductivity type is formed beneath the top surface 41a in the drift well region 42 of the semiconductor layer 41′, and in contact with the top surface 41a in the vertical direction. From top view, the drain 49 is between the first drift oxide region 44 and the isolation oxide region 43. The source 48 is located in the channel well region 46 outside the gate 47 and the drain 49 is located in the drift well region 42 at a location away from the channel well region 46 in the lateral direction. The drift region 42a is defined between the drain 49 and the channel well region 46 in the drift well region 42 and near the top surface 41a, to serve as the drift region during ON operation of the high voltage device 400.

The isolation oxide region 43, the first drift oxide region 44, and the second drift oxide region 45 have an insulation thickness di, a first thickness d1, and a second thickness d2 in the vertical direction, respectively, and the second thickness d2 is less than the first thickness D1. The second drift oxide region 45 is a chemical vapor deposition (CVD) oxide region formed by a CVD process step; the CVD process step is well known to a person having ordinary skill in the art, so the details thereof are not redundantly explained here. The first drift oxide region 44 is a local oxidation of silicon (LOCOS) structure as shown in the figure. The second thickness d2 is larger than a dielectric layer thickness dk of the dielectric layer 47a.

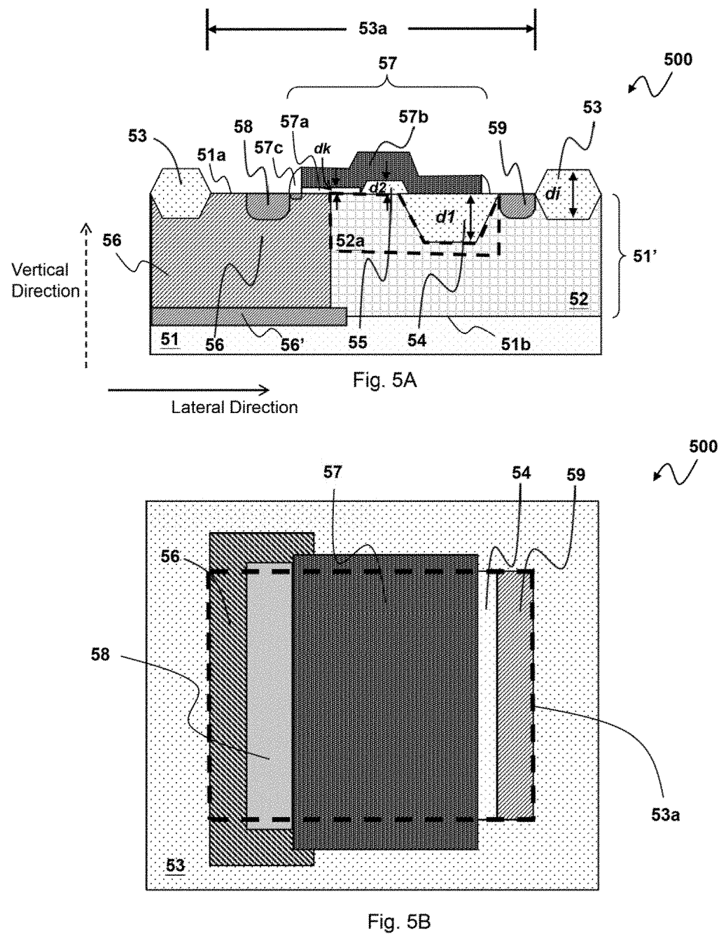

FIGS. 5A and 5B show a fourth embodiment of the present invention. FIGS. 5A and 5B respectively show a cross-sectional view and a top view of a high voltage device 500. The high voltage device 500 includes a semiconductor layer 51′, a drift well region 52, a buried layer 56′, an isolation oxide region 53, a first drift oxide region 54, a second drift oxide region 55, a channel well region 56, a gate 57, a source 58, and a drain 59. The semiconductor layer 51′ is formed on the substrate 51, and the semiconductor layer 51′ has a top surface 51a and a bottom surface 51b that is opposite to the top surface 51a in a vertical direction (as indicated by the direction of the dashed arrow in FIG. 5A). The substrate 51 is, for example but not limited to, a P-type or N-type semiconductor silicon substrate. The semiconductor layer 51′, for example, is formed on the substrate 51 by epitaxy, or, a part of the substrate 51 forms the semiconductor layer 51′. The method of forming the semiconductor layer 51′ is known to a person having ordinary skill in the art, so the details thereof are not redundantly explained here.

Still referring to FIGS. 5A and 5B, the isolation oxide region 53 is formed on the top surface 51a and in contact with the top surface 51a for defining an operation region 53a (as indicated by the dashed line in FIG. 5B). The isolation oxide region 53 is not limited to the local oxidation of silicon (LOCOS) structure as shown in the figure, and may instead be a shallow trench isolation (STI) structure. The first drift oxide region 54 is formed on the top surface 51a and in contact with the top surface 51a, and is located on the drift region 52a (as indicated by the dashed line in FIG. 5A) in the operation region 53a and in contact with the drift region 52a. The second drift oxide region 55 is formed on the top surface 51a and in contact with the top surface 51a, and is located on the drift region 52a in the operation region 53a and in contact with the drift region 52a, and the second drift oxide region 55 is in contact with the first drift oxide region 54 in a lateral direction (as indicated by the direction of the solid arrow in FIG. 5A).

The drift well region 52 which has a first conductivity type is formed in the operation region 53a of the semiconductor layer 51′, and the drift well region 52 is located beneath the top surface 51a and in contact with the top surface 51a in the vertical direction. The channel well region 56 (or a portion thereof) which has a second conductivity type is formed in the operation region 53a of the semiconductor layer 51′, and the channel well region 56 is located beneath the top surface 51a and in contact with the top surface 51a in the vertical direction. The buried layer 56′ which has the first conductivity type is formed beneath the channel well region 56 and in contact with the channel well region 56, and the buried layer 56′ covers the whole lower side of at least the portion of the channel well region 56 in the operation region 53a. The gate 57 is formed on the top surface 51a in the operation region 53a of the semiconductor layer 51′. As viewing from above (i.e., from top view), the gate 57 covers all the second drift oxide region 55 and at least a portion of the first drift oxide region 54; a portion of the channel well region 56 is located beneath the gate 57 and in contact with the gate 57 in the vertical direction, to provide an inverse current channel during ON operation of the high voltage device 500.

Still referring to FIGS. 5A and 5B, the gate 57 includes a dielectric layer 57a, a conductive layer 57b, and a spacer layer 57c. The dielectric layer 57a is formed on the top surface 51a and in contact with the top surface 51a, and in contact with the second drift oxide region 55 in the lateral direction, and the dielectric layer 57a and the first drift oxide region 54 are separated by the second drift oxide region 55. The conductive layer 57b which is provided as an electrical contact of the gate 57 is formed on all the dielectric layers 57a and in contact with the dielectric layer 57a, and is formed on all the second drift oxide regions 55 and in contact with the second drift oxide region 55, and is formed on at least a portion of the first drift oxide region 54 and in contact with the first drift oxide region 54. The spacer layer 57c is formed outside the sidewalls of the conductive layer 57b and in contact with the conductive layer 57b so as to serve as an electrical insulation layer of the gate 57.

The source 58 which has the first conductivity type is formed beneath the top surface 51a in the channel well region 56 of the semiconductor layer 51′, and in contact with the top surface 51a in the vertical direction. The drain 59 which has the first conductivity type is formed beneath the top surface 51a in the drift well region 52 of the semiconductor layer 51′, and in contact with the top surface 51a in the vertical direction. From top view, the drain 59 is between the first drift oxide region 54 and the isolation oxide region 53. The source 58 is located in the channel well region 56 outside the gate 57 and the drain 59 is located in the drift well region 52 at a location away from the channel well region 56 in the lateral direction. The drift region 52a is defined between the drain 59 and the channel well region 56 in the drift well region 52 and near the top surface 51a, to serve as the drift region during ON operation of the high voltage device 500.

The isolation oxide region 53, the first drift oxide region 54, and the second drift oxide region 55 have an insulation thickness di, a first thickness d1, and a second thickness d2 in the vertical direction, respectively, and the second thickness d2 is less than the first thickness D1. The second drift oxide region 55 is a chemical vapor deposition (CVD) oxide region formed by a CVD process step; the CVD process step is well known to a person having ordinary skill in the art, so the details thereof are not redundantly explained here. The first drift oxide region 54 is a shallow trench isolation (STI) region as shown in the figure. The second thickness d2 is larger than a dielectric layer thickness dk of the dielectric layer 57a.

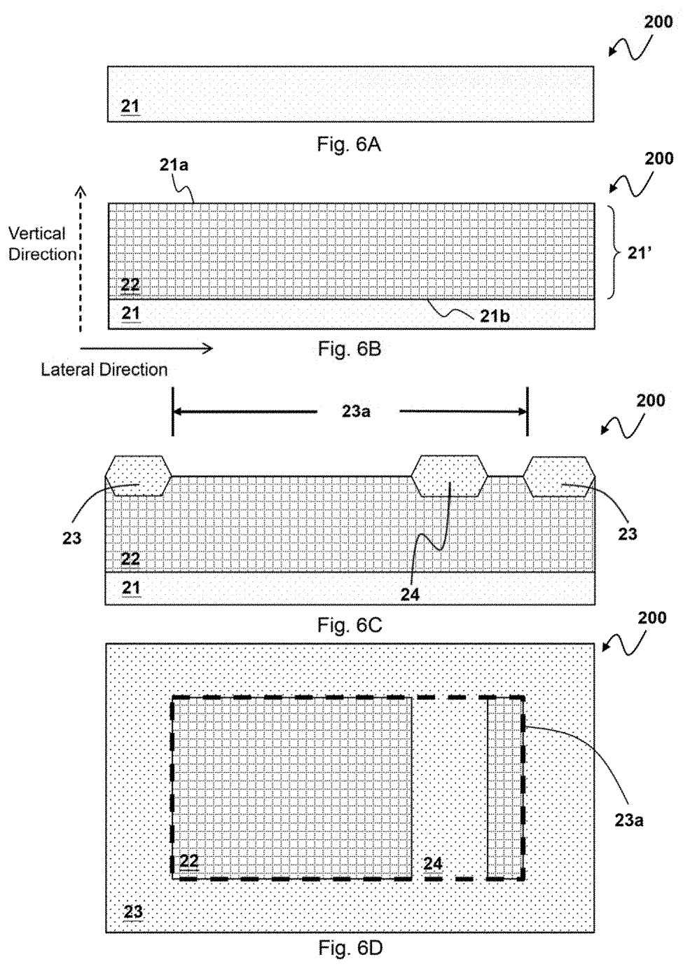

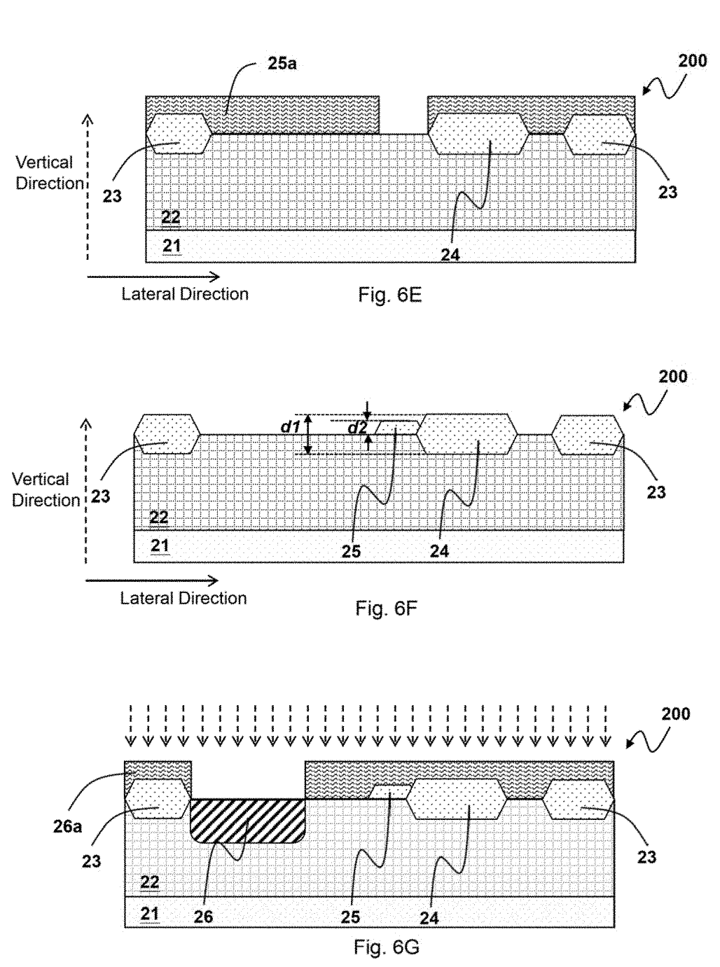

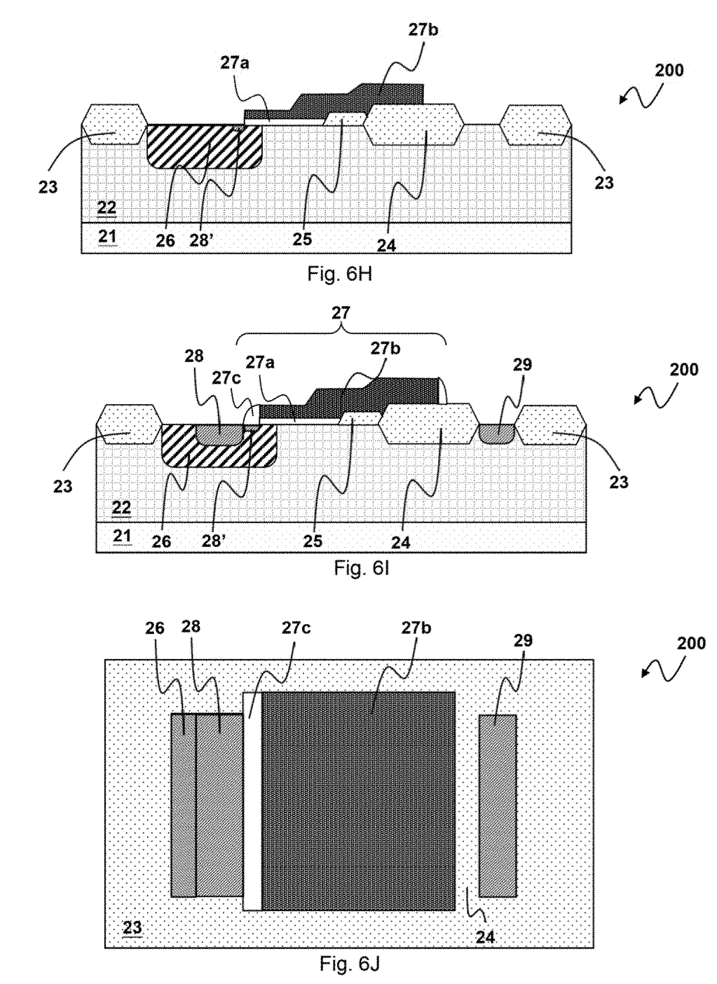

FIGS. 6A to 6J show a fifth embodiment of the present invention. FIGS. 6A to 6C and FIGS. 6E to 6I are cross-sectional views showing a manufacturing method of a lateral double-diffused metal oxide semiconductor (LDMOS) device 200 according to the present invention, and FIG. 6D and FIG. 6J respectively show top views of FIG. 6C and FIG. 6I. First, as shown in FIG. 6A, a substrate 21 is provided. The substrate 21 is, for example but not limited to, a P-type or N-type semiconductor silicon substrate, or any other kind of semiconductor substrate.

Next, as shown in FIG. 6B, the semiconductor layer 21′ is formed on the substrate 21. The semiconductor layer 21′ has a top surface 21a and a bottom surface 21b in the vertical direction (as indicated by the direction of the dashed arrow in FIG. 6B). The semiconductor layer 21′ is formed on the substrate 21, for example, by epitaxy, or a portion of the substrate 21 is used to form the semiconductor layer 21′. The semiconductor layer 21′ can be formed by any method known to a person having ordinary skill in the art, so the details thereof are not redundantly explained here. Next, the well region 22 which has the first conductivity type is formed in the operation region 23a of the semiconductor layer 21′, and the well region 22 is located beneath the top surface 21a and in contact with the top surface 21a in the vertical direction. The well region 22 can be formed by, for example but not limited to, an ion implantation process which implants first conductivity type impurities in the form of accelerated ions into the semiconductor layer 21′ to form the well region 22.

Next, as shown in FIG. 6C, the isolation oxide region 23 and the first drift oxide region 24 are formed on the top surface 21a and in contact with the top surface 21a. The isolation oxide region 23 is for defining the operation region 23a. The operation region 23a serves as a main function region within which the LDMOS device 200 operates, and its range is as indicated by a thick black dashed line in the FIG. 6D. The isolation oxide region 23 and the first drift oxide region 24 are, for example but not limited to, local oxidation of silicon (LOCOS) structure, and they may be formed concurrently by using the same process steps. The first drift oxide region 24 is located on the drift region 22a in the operation region 23a and in contact with the drift region 22a (see FIG. 2A).

Next, as shown in FIG. 6E, the second drift oxide region 25 is defined by using a mask layer 25a, wherein the mask layer 25a includes, for example but not limited to, a nitride layer (such as silicon nitride) or any other hard mask layer which can block the oxidation process. Next, as shown in FIG. 6F, the second drift oxide region 25 is formed, and thereafter the mask layer 25a is removed. In this way, the thickness of the second drift oxide region 25 is less than the thickness of the first drift oxide region 24 in the vertical direction (as indicated by the dashed arrow in FIG. 6E), while the thickness of the first drift oxide region 24 is not affected. As shown in FIG. 6F, the first drift oxide region 24 has a thickness d1 in the vertical direction, which is larger than the thickness d2 of the second drift oxide region 25 in the vertical direction. The second drift oxide region 25 is in contact with the first drift oxide region 24 in the lateral direction as indicated by the arrow in FIG. 6F. The second drift oxide region 25 is a chemical vapor deposition (CVD) oxide region formed by a CVD process step. The first drift oxide region 24 is, for example but not limited to, a local oxidation of silicon (LOCOS) structure (as shown in the figure) or a shallow trench isolation (STI) structure (e.g. 34 in FIG. 3A).

Next, as shown in FIG. 6G, in one embodiment, a photoresist layer 26a is formed as a mask by a lithography process to define the body region 26, and an ion implantation process implants second conductive type impurities in the form of accelerated ions, as indicated by the dashed arrows in FIG. 6G, into the defined region to form the body region 26 in the well region 22, and thereafter the photoresist layer 26a is removed.

Next, as shown in FIG. 6H, the dielectric layer 27a is formed on the drift region 22a and in contact with the drift region 22a in the vertical direction, and the dielectric layer 27a is in contact with the second drift oxide region 25 in the lateral direction. The dielectric layer 27a and the first drift oxide region 24 are spaced apart by the second drift oxide region 25 in the lateral direction. The dielectric layer 27a has a dielectric constant higher than the dielectric constant of silicon or the substrate 21. Next, the conductive layer 27b is formed on the dielectric layer 27a and is used as an electrical contact of the gate 27; the conductive layer 27b comprises a conductive material, for example but not limited to, a metal or a polysilicon doped with P-type or N-type impurities. In addition to covering the dielectric layer 27a, the conductive layer 27b covers all the second drift oxide region 25 and a portion of the first drift oxide region 24. Next, a lightly-doped region 28′ is formed in the body region 26 by using the conductive layer 27b as a mask. The lightly doped region 28′ has the same conductivity type as the drift region 22; in the present embodiment, for example, the lightly-doped region 28′ is of the first conductivity type. The lightly-doped region 28′ electrically connects the source 28 and the inverse current channel.

Next, as shown in FIG. 6I, the spacer layer 27c is formed on the top surface 21a outside the sidewalls of the conductive layer 27b, and covers the sidewalls of the conductive layer 27b; the spacer layer 27c is formed by an insulation material and can be used as a self-aligned mask to form the source 28. The source 28 is next formed in the body region 26, and the source 28 has the same conductivity type as the well region 22, which is the first conductivity type in the present embodiment. As viewing from the top view of FIG. 6J, the spacer layer 27c is located between the source 28 and the conductive layer 27b in the lateral direction. The drain 29 is formed in the well region 22 and has the same conductivity type as the well region 22, which is the first conductivity type in the present embodiment, and as viewing from the cross-sectional view of FIG. 6I, the drain 29 is located between the first drift oxide region 24 and the isolation oxide region 23 in the lateral direction. From the top view of FIG. 6J, the isolation oxide region 23, the drain 29, the first drift oxide region 24, the second drift oxide region 25, and the dielectric layer 27a are arranged in a sequential order in the lateral direction from right to left.

The main difference between the present invention and the prior art is that a portion of the drift oxide region beneath the gate near the source side in the prior art is replaced by a CVD oxide region having a less thickness (comparing the first drift oxide region 14 in FIG. 1A with the second drift oxide region 25 in FIG. 6I), so that the on-resistance can be lowered, the on-current can be increased, and the speed and application range of the device can be increased without lowering the breakdown protection voltage.

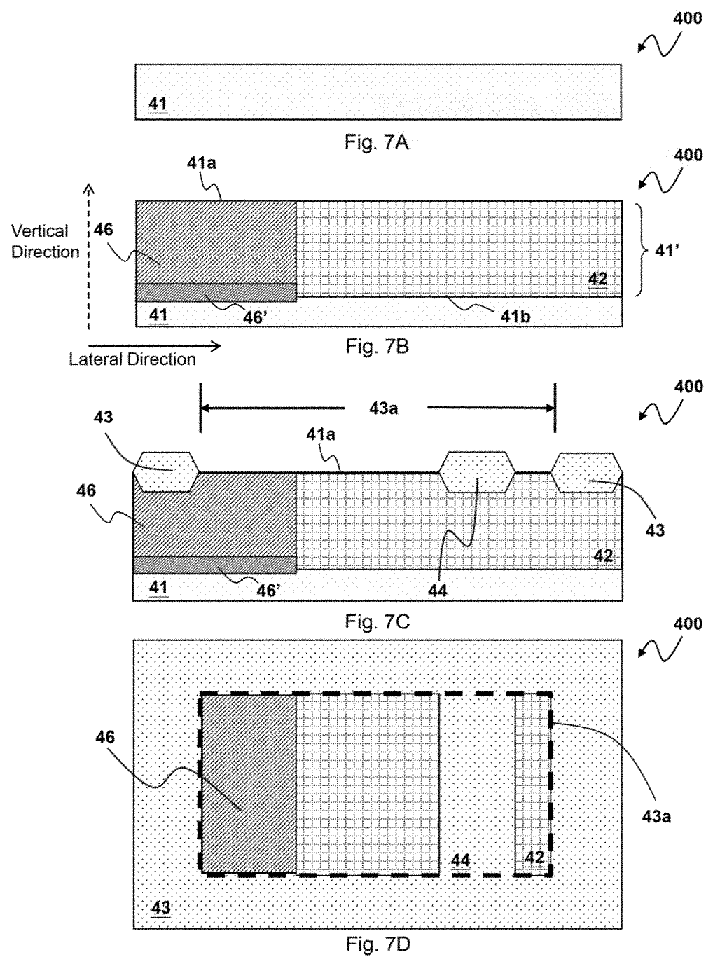

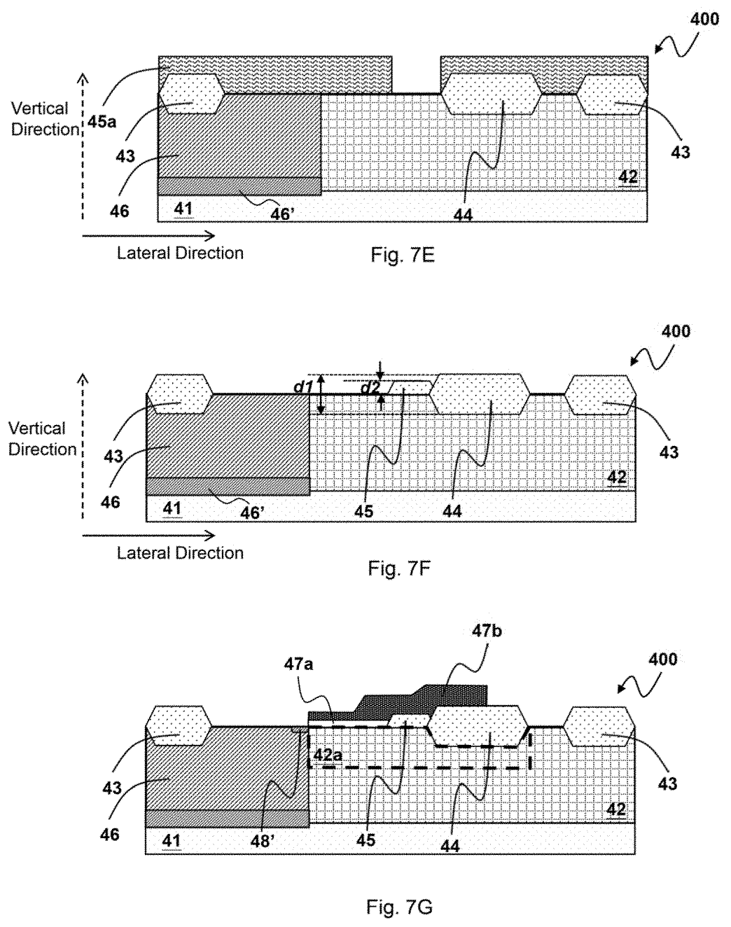

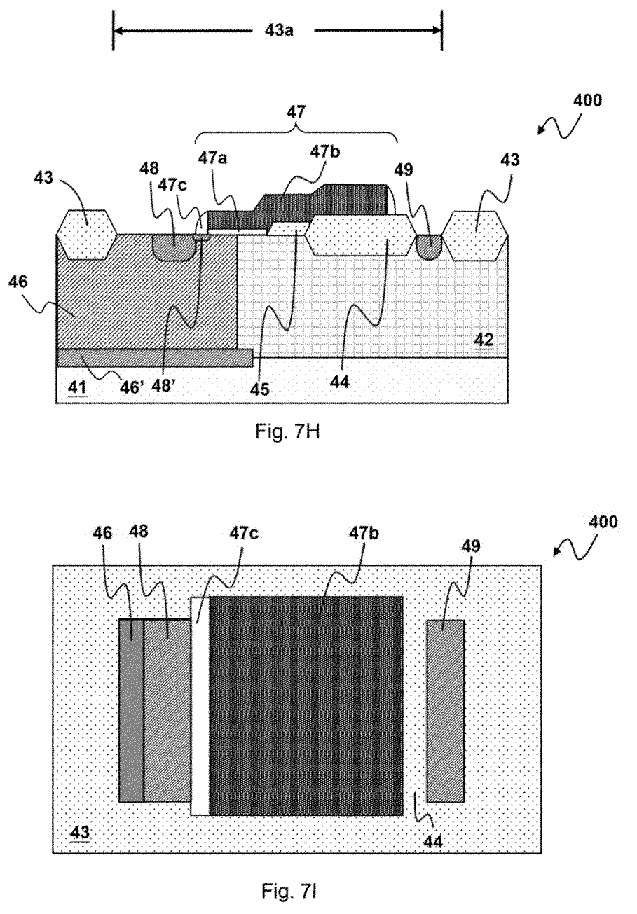

FIGS. 7A to 7I show a sixth embodiment of the present invention. FIGS. 7A to 7C and FIGS. 7E to 7H are cross-sectional views showing a manufacturing method of a lateral double-diffused metal oxide semiconductor (LDMOS) device 400 according to the present invention, and FIG. 7D and FIG. 7I respectively show top views of FIG. 7C and FIG. 7H. First, as shown in FIG. 7A, a substrate 41 is provided, and the substrate 41 is, for example but not limited to, a P-type or N-type semiconductor silicon substrate, or any other kind of semiconductor substrate.

Next, as shown in FIG. 7B, the semiconductor layer 41′ is formed on the substrate 41. The semiconductor layer 41′ has a top surface 41a and a bottom surface 41b in the vertical direction (as indicated by the direction of the dashed arrow in FIG. 6B). The semiconductor layer 41′ is formed on the substrate 41, for example, by epitaxy, or a portion of the substrate 41 is used to form the semiconductor layer 41′. The semiconductor layer 41′ can be formed by any method known to a person having ordinary skill in the art, so the details thereof are not redundantly explained here. Next, the drift well region 42 and the channel well region 46 are formed in the operation region 43a of the semiconductor layer 41′, wherein the drift well region 42 has the first conductivity type, and the channel well region 46 has the second conductivity type. In the vertical direction, the drift well region 42 and the channel well region 46 are located beneath the top surface 41a and in contact with the top surface 41a. The drift well region 42 can be formed by, for example but not limited to, an ion implantation process which implants first conductivity type impurities into a region defined in the semiconductor layer 41′ in the form of accelerated ions, to form the drift well region 42. The channel well region 46 can be formed by, for example but not limited to, an ion implantation process which implants second conductivity type impurities in the form of an accelerated ion into a region defined in the semiconductor layer 41′, to form the channel well region 46. The channel well region 46 is in contact with the drift well region 42 in the lateral direction. Next, the buried layer 46′ is formed beneath the channel well region 46 and in contact with the channel well region, and the buried layer 46′ completely covers the portion of the channel well region 46 in the operation region 43a, wherein the buried layer 46′ has the first conductivity type.

Next, as shown in FIG. 7C, the isolation oxide region 43 and the first drift oxide region 44 are formed on the top surface 41a and in contact with the top surface 41a. The isolation oxide region 43 is for defining the operation region 43a. The operation region 43a serves as a main function region within which the LDMOS device 400 operates, and its range is as indicated by a thick black dashed line in the FIG. 7D. The isolation oxide region 43 and the first drift oxide region 44 are, for example but not limited to, local oxidation of silicon (LOCOS) structure, and they may be formed concurrently by using the same process steps. The first drift oxide region 44 is located on the drift region 42a in the operation region 43a and in contact with the drift region 42a (see FIG. 4A).

Next, as shown in FIG. 7E, the second drift oxide region 45 is defined by using a mask layer 45a, wherein the mask layer 45a includes, for example but not limited to, a nitride layer (such as silicon nitride) or any other hard mask layer which can block the oxidation process. Next, as shown in FIG. 7F, the second drift oxide region 45 is formed, and thereafter the mask layer 45a is removed. In this way, the thickness of the second drift oxide region 45 is less than the thickness of the first drift oxide region 44 in the vertical direction (as indicated by the dashed arrow in FIG. 7E), while the thickness of the first drift oxide region 44 is not affected. As shown in FIG. 7F, the first drift oxide region 44 has a thickness d1 in the vertical direction, which is larger than the thickness d2 of the second drift oxide region 45 in the vertical direction. The second drift oxide region 45 is in contact with the first drift oxide region 44 in the lateral direction as indicated by the arrow in FIG. 7F. The second drift oxide region 45 is a chemical vapor deposition (CVD) oxide region formed by a CVD process step. The first drift oxide region 44 is, for example but not limited to, a local oxidation of silicon (LOCOS) structure (as shown in the figure) or a shallow trench isolation (STI) structure (e.g. 54 in FIG. 5A).

Next, as shown in FIG. 7G, the dielectric layer 47a is formed on the drift region 42a and in contact with the drift region 42a in the vertical direction and in contact with the second drift oxide region 45 in the lateral direction. The dielectric layer 47a and the first drift oxide region 44 are separated by the second drift oxide region 45 in the lateral direction. The dielectric layer 47a has a dielectric constant higher than the dielectric constant of the silicon nitride or substrate 41. Next, the conductive layer 47b is formed on the dielectric layer 47a, and the conductive layer 47b which is used as an electrical contact of the gate 47 comprises a conductive material, for example but not limited to, a metal or a polysilicon doped with P-type or N-type impurities. In addition to covering the dielectric layer 47a, the conductive layer 47b covers all the second drift oxide region 45 and a portion of the first drift oxide region 44. Next, a lightly-doped region 48′ is formed in the channel well region 46 by using the conductive layer 47b as a mask. The lightly doped region 48′ has the same conductivity type as the drift well region 42 in the present embodiment, which is for example the first conductivity type, to electrically connect the source 48 to the inverse current channel.

Next, as shown in FIG. 7H, the spacer layer 47c is formed on the top surface 41a outside the sidewalls of the conductive layer 47b, and covers the sidewalls of the conductive layer 47b; the spacer layer 47c is formed by an insulation material and can be used as a self-aligned mask to form the source 48. The source 48 is next formed in the channel well region 46, and the source 48 has the same conductivity type as the drift well region 42 in the present embodiment, which is for example the first conductivity type. As viewing from the top view of FIG. 7I, the spacer layer 47c is located between the source 28 and the conductive layer 47b in the lateral direction. The drain 49 has the same conductivity type as the drift well region 42 in this embodiment which is for example the first conductivity type; the drain 49 is formed in the drift well region 42, and as shown in the cross-sectional view of FIG. 7H, the drain 49 is located between the first drift oxide region 44 and the isolation oxide region 43 in the lateral direction. As from the top view of FIG. 7I, the first drift oxide region 44, the second drift oxide region 45, and the dielectric layer 47a are arranged in a sequential order in the lateral direction from right to left.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well region, may be added. For another example, the lithography technique is not limited to the mask technology but it can be electron beam lithography, immersion lithography, etc. Therefore, in the same spirit of the present invention, those skilled in the art can think of various equivalent variations and modifications, which should fall in the scope of the claims and the equivalents.

What is claimed is:

1. A lateral double diffused metal oxide semiconductor (LDMOS) device comprising:
a semiconductor layer formed on a substrate, wherein the semiconductor layer has a top surface and a bottom surface that is opposite to the top surface in a vertical direction;
an isolation oxide region formed on the top surface and in contact with the top surface, wherein the isolation oxide region defines an operation region;
a first drift oxide region formed on the top surface and in contact with the top surface, wherein the first drift oxide region is located on a drift region in the operation region and in contact with the drift region;
a second drift oxide region formed on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction;
a well region having a first conductivity type, wherein the well region is formed in the operation region of the semiconductor layer and is located beneath the top surface and in contact with the top surface in the vertical direction;
a body region having a second conductivity type, wherein the body region is formed in the well region of the operation region and is located beneath the top surface and in contact with the top surface;
a gate formed on the top surface in the operation region of the semiconductor layer, wherein the gate covers all the second drift oxide region and at least a portion of the first drift oxide region, and wherein the gate comprises:
a dielectric layer formed on the the top surface and in contact with the top surface, wherein the dielectric layer is in contact with the second drift oxide region in the lateral direction, and the dielectric layer and the first drift oxide region and are separated by the second drift oxide region;
a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and
a spacer layer formed outside sidewalls of the conductive layer, wherein the spacer layer is in contact with the conductive layer and serves as an electrical insulation layer of the gate;
a source having the first conductivity type, wherein the source is formed beneath the top surface and in contact with the top surface in the vertical direction in the body region of the semiconductor layer; and
a drain having the first conductivity type, wherein the drain is formed beneath the top surface and in contact with the top surface in the vertical direction in the well region of the semiconductor layer, and the drain is located between the first drift oxide region and the isolation oxide region;
wherein the source is located in the body region outside the gate and the drain is located at a location in the well region which is away from the body region;
wherein the drift region is defined as a region between the drain and the body region in the well region and near the top surface, for ON operation of the high voltage device;
wherein the isolation oxide region, the first drift oxide region, and the second drift oxide region have an isolation thickness, a first thickness, and a second thickness respectively in the vertical direction, wherein the second thickness is less than the first thickness;
wherein the second drift oxide region is a chemical vapor deposition (CVD) oxide region which is formed by a CVD process step;
wherein the first drift oxide region is a local oxidation of silicon (LOCOS) structure or a shallow trench isolation (STI) structure; and
wherein the second thickness is larger than a dielectric layer thickness of the dielectric layer.

2. The LDMOS device of claim 1, wherein the isolation oxide region, the drain, the first drift oxide region, the second drift oxide region and the dielectric layer are arranged in a sequential order in the lateral direction.

3. The LDMOS device of claim 1, further including a body electrode having the second conductivity type, wherein the body electrode is formed in the body region and serves as an electrical contact of the body region.

4. A manufacturing method of a lateral double diffused metal oxide semiconductor (LDMOS), comprising:
forming a semiconductor layer on a substrate, wherein the semiconductor layer has a top surface and a bottom surface that is opposite to the top surface in a vertical direction;
forming an isolation oxide region on the top surface and in contact with the top surface, wherein the isolation oxide region defines an operation region;
forming a first drift oxide region on the top surface and in contact with the top surface, wherein the first drift oxide region is located on a drift region in the operation region and in contact with the drift region;
forming a second drift oxide region on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction;
forming a well region having a first conductivity type, wherein the well region is formed in the operation region of the semiconductor layer and is located beneath the top surface and in contact with the top surface in the vertical direction;
forming a body region having a second conductivity type, wherein the body region is formed in the well region of the operation region and is located beneath the top surface and in contact with the top surface;
forming a gate on the top surface in the operation region of the semiconductor layer, wherein the gate covers all the second drift oxide region and at least a portion of the first drift oxide region, and wherein the gate comprises:
a dielectric layer formed on the the top surface and in contact with the top surface, wherein the dielectric layer is in contact with the second drift oxide region in the lateral direction, and the dielectric layer and the first drift oxide region and are separated by the second drift oxide region;
a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and
a spacer layer formed outside sidewalls of the conductive layer, wherein the spacer layer is in contact with the conductive layer and serves as an electrical insulation layer of the gate;
forming a source having the first conductivity type, wherein the source is formed beneath the top surface and in contact with the top surface in the vertical direction in the body region of the semiconductor layer; and
forming a drain having the first conductivity type, wherein the drain is formed beneath the top surface and in contact with the top surface in the vertical direction in the well region of the semiconductor layer, and the drain is located between the first drift oxide region and the isolation oxide region;
wherein the source is located in the body region outside the gate and the drain is located at a location in the well region which is away from the body region;
wherein the drift region is defined as a region between the drain and the body region in the well region and near the top surface, for ON operation of the high voltage device;
wherein the isolation oxide region, the first drift oxide region, and the second drift oxide region have an isolation thickness, a first thickness, and a second thickness respectively in the vertical direction, wherein the second thickness is less than the first thickness;
wherein the second drift oxide region is a chemical vapor deposition (CVD) oxide region which is formed by a CVD process step;
wherein the first drift oxide region is a local oxidation of silicon (LOCOS) structure or a shallow trench isolation (STI) structure; and
wherein the second thickness is larger than a dielectric layer thickness of the dielectric layer.

5. The manufacturing method of the LDMOS device of claim 4, wherein the isolation oxide region, the drain, the first drift oxide region, the second drift oxide region and the dielectric layer are arranged in a sequential order in the lateral direction.

6. The manufacturing method of the LDMOS device of claim 4, further including: forming a body electrode having the second conductivity type in the body region, to serve as an electrical contact of the body region.

7. A lateral double diffused metal oxide semiconductor (LDMOS) device comprising:
a semiconductor layer formed on a substrate, wherein the semiconductor layer has a top surface and a bottom surface that is opposite to the top surface in a vertical direction;
an isolation oxide region formed on the top surface and in contact with the top surface, wherein the isolation oxide region defines an operation region;
a first drift oxide region formed on the top surface and in contact with the top surface, wherein the first drift oxide region is located on a drift region in the operation region and in contact with the drift region;
a second drift oxide region formed on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction;
a drift well region having a first conductivity type, wherein the drift well region is formed in the operation region of the semiconductor layer and is located beneath the top surface and in contact with the top surface in the vertical direction;
a channel well region having a second conductivity type, wherein the channel well region is formed at least in the operation region beneath the top surface in the vertical direction and in contact with the drift well region in the lateral direction;
a buried layer having the first conductivity type, wherein the buried layer is formed beneath the channel well region and in contact with the channel well region in the vertical direction, and wherein the buried layer completely covers a portion of the the channel well region in the operation region;
a gate formed on the top surface in the operation region of the semiconductor layer, wherein the gate covers all the second drift oxide region and at least a portion of the first drift oxide region, and wherein the gate comprises:
a dielectric layer formed on the the top surface and in contact with the top surface, wherein the dielectric layer is in contact with the second drift oxide region in the lateral direction, and the dielectric layer and the first drift oxide region and are separated by the second drift oxide region;
a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and
a spacer layer formed outside sidewalls of the conductive layer, wherein the spacer layer is in contact with the conductive layer and serves as an electrical insulation layer of the gate;
a source having the first conductivity type, wherein the source is formed beneath the top surface and in contact with the top surface in the vertical direction in the channel well region of the semiconductor layer; and
a drain having the first conductivity type, wherein the drain is formed beneath the top surface and in contact with the top surface in the vertical direction in the drift well region of the semiconductor layer, and the drain is located between the first drift region and the isolation oxide region;
wherein the source is located in the channel well region outside the gate and the drain is located at a location in the drift well region which is away from the channel well region;
wherein the drift region is defined as a region between the drain and the channel well region in the drift well region and near the top surface, for ON operation of the high voltage device;
wherein the isolation oxide region, the first drift oxide region, and the second drift oxide region have an isolation thickness, a first thickness, and a second thickness respectively in the vertical direction, wherein the second thickness is less than the first thickness;
wherein the second drift oxide region is a chemical vapor deposition (CVD) oxide region which is formed by a CVD process step;
wherein the first drift oxide region is a local oxidation of silicon (LOCOS) structure or a shallow trench isolation (STI) structure; and
wherein the second thickness is larger than a dielectric layer thickness of the dielectric layer.

8. The LDMOS device of claim 7, wherein the isolation oxide region, the drain, the first drift oxide region, the second drift oxide region and the dielectric layer are arranged in a sequential order in the lateral direction.

9. A manufacturing method of a lateral double diffused metal oxide semiconductor (LDMOS) device, comprising:
forming a semiconductor layer on a substrate, wherein the semiconductor layer has a top surface and a bottom surface that is opposite to the top surface in a vertical direction;
forming an isolation oxide region on the top surface and in contact with the top surface, wherein the isolation oxide region defines an operation region;
forming a first drift oxide region on the top surface and in contact with the top surface, wherein the first drift oxide region is located on a drift region in the operation region and in contact with the drift region;
forming a second drift oxide region on the top surface and in contact with the top surface, wherein the second drift oxide region is located on the drift region in the operation region and in contact with the drift region, wherein the second drift oxide region is in contact with the first drift oxide region in a lateral direction perpendicular to the vertical direction;
forming a drift well region having a first conductivity type, wherein the drift well region is formed in the operation region of the semiconductor layer and is located beneath the top surface and in contact with the top surface in the vertical direction;
forming a channel well region having a second conductivity type, wherein the channel well region is formed at least in the operation region beneath the top surface in the vertical direction and in contact with the drift well region in the lateral direction;
forming a buried layer having the first conductivity type, wherein the buried layer is formed beneath the channel well region and in contact with the channel well region in the vertical direction, and wherein the buried layer completely covers a portion of the the channel well region in the operation region;
forming a gate on the top surface in the operation region of the semiconductor layer, wherein the gate covers all the second drift oxide region and at least a portion of the first drift oxide region, and wherein the gate comprises:
a dielectric layer formed on the the top surface and in contact with the top surface, wherein the dielectric layer is in contact with the second drift oxide region in the lateral direction, and the dielectric layer and the first drift oxide region and are separated by the second drift oxide region;
a conductive layer, serving as an electrical contact of the gate, wherein the conductive layer is formed on all the dielectric layer and in contact with the dielectric layer, and is formed on all the second drift oxide region and in contact with the second drift oxide region, and is formed on a portion of the first drift oxide region and in contact with the the first drift oxide region; and
a spacer layer formed outside sidewalls of the conductive layer, wherein the spacer layer is in contact with the conductive layer and serves as an electrical insulation layer of the gate;
forming a source having the first conductivity type, wherein the source is formed beneath the top surface and in contact with the top surface in the vertical direction in the channel well region of the semiconductor layer; and
forming a drain having the first conductivity type, wherein the drain is formed beneath the top surface and in contact with the top surface in the vertical direction in the drift well region of the semiconductor layer, and the drain is located between the first drift region and the isolation oxide region;
wherein the source is located in the channel well region outside the gate and the drain is located at a location in the drift well region which is away from the channel well region;
wherein the drift region is defined as a region between the drain and the channel well region in the drift well region and near the top surface, for ON operation of the high voltage device;
wherein the isolation oxide region, the first drift oxide region, and the second drift oxide region have an isolation thickness, a first thickness, and a second thickness respectively in the vertical direction, wherein the second thickness is less than the first thickness;
wherein the second drift oxide region is a chemical vapor deposition (CVD) oxide region which is formed by a CVD process step;
wherein the first drift oxide region is a local oxidation of silicon (LOCOS) structure or a shallow trench isolation (STI) structure; and
wherein the second thickness is larger than a dielectric layer thickness of the dielectric layer.

10. The manufacturing method of the LDMOS device of claim 9, wherein the isolation oxide region, the drain, the first drift oxide region, the second drift oxide region and the dielectric layer are arranged in a sequential order in the lateral direction.
